(19) United States
(12) Patent Application Publication
(10) Pub. No.: US 2025/0125304 A1
(43) Pub. Date: Apr. 17, 2025

(54) METHOD OF MANUFACTURING A CHIP STRUCTURE AND CHIP STRUCTURE

(71) Applicant: Infineon Technologies AG, Neubiberg (DE)

(72) Inventors: Joachim MAHLER, Regensburg-Leoprechting (DE); Peter STROBEL, Regensburg (DE); Franz ZOLLNER, Sinzing (DE)

(73) Assignee: Infineon Technologies AG, Neubiberg (DE)

(21) Appl. No.: 18/910,598

(22) Filed: Oct. 9, 2024

(30) Foreign Application Priority Data
Oct. 17, 2023 (DE) 10 2023 128 377.4

(51) Int. Cl. H01L 23/00

(52) U.S. Cl. CPC H01L 24/83; H01L 24/29; H01L 24/32; H01L 2224/29109; H01L 2224/29111; H01L 2224/32225; H01L 2224/32503; H01L 2224/8381

(57) ABSTRACT

A method of manufacturing a chip structure is provided. The method includes attaching a chip to a chip carrier using a chip attach layer, wherein the chip attach layer comprises a metal having a first melting point. The chip comprises a solder layer and the chip carrier comprises a further solder layer, the solder layer and/or the further solder layer comprising a respective solder material having a second melting point lower than the first melting point. An intermetallic phase is formed between the solder material and metal of the chip attach layer by melting the solder material having the second melting point.

### CROSS-REFERENCE TO RELATED APPLICATION

This Utility Patent Application claims priority to German Patent Application No. 10 2023 128 377.4 filed Oct. 17, 2023, which is incorporated herein by reference.

### TECHNICAL FIELD

Various embodiments relate generally to a method of manufacturing a chip structure and to a chip structure.

### BACKGROUND

Chip structures that include a chip soldered to a carrier often suffer from a reliability problem regarding the solder connection, which may mean that the solder connection may at least partially break, for example due to stress and/or thermal cycling. Alternatively or additionally, a (thermal and/or electrical) conductivity may be low.

### SUMMARY

A method of manufacturing a chip structure is provided. The method includes attaching a chip to a chip carrier using a chip attach layer, wherein the chip attach layer comprises a metal having a first melting point, wherein the chip comprises a solder layer and the chip carrier comprises a further solder layer, the solder layer and the further solder layer comprising a respective solder material having a second melting point lower than the first melting point, and forming an intermetallic phase between the solder material and metal of the chip attach layer by melting the solder material.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 illustrates a method of manufacturing a chip structure in accordance with various embodiments, and shows a schematic cross-sectional view of the resulting chip structure in accordance with various embodiments;

FIG. 2 shows distributions of six different elements over the cross-section of a chip structure in accordance with various embodiments obtained via scanning electron microscopy;

FIG. 3 shows an electron microscopy image of the cross-section of the chip structure of FIG. 2;

FIG. 4 shows distributions of six different elements over the cross-section of a further chip structure in accordance with various embodiments obtained via scanning electron microscopy;

FIG. 5 shows an electron microscopy image of the cross-section of the further chip structure of FIG. 4 in an area that extends beyond the portion shown in FIG. 4;

FIG. 6 shows distributions of six different elements over the cross-section of a yet further chip structure in accordance with various embodiments obtained via scanning electron microscopy;

FIG. 7 shows an electron microscopy image of a cross-section of a further chip structure in accordance with various embodiments; and

FIG. 8 shows a flow diagram of a method of manufacturing a chip structure in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

In various embodiments, a heat initiated intermetallic reaction is used for forming a reliable bond between a chip (also referred to as “die”) and a chip carrier.

The heat initiated intermetallic reaction may take place between solder material arranged on the chip and/or the chip carrier, respectively, as one of the reaction partners, and metal of a chip attach layer arranged between the (solder material of the) chip and the (solder material of the) chip carrier.

In various embodiments, the metal on top of the one or two bonding surfaces may melt during a die attach curing process (which means that a curing temperature of the die attach process may be higher than a melting temperature of the top metal layer(s)).

For the die attach, a paste including metal particle fillers in a paste or film (which may additionally include organic parts like resin(s), solvent(s)/liquid(s) and/or additives like fluxes, surface reactive and activation substances) may be used.

The melted metal from the bonding surface(s) may form an intermetallic component, for example an intermetallic phase, in combination with the metal particle fillers of the die attach paste, in the bonding layer.

Thereby, an increased heat dissipation may be enabled and a higher reliability may be achieved. This may be particularly useful for new wide band-gap semiconductors (e. g., GaN, SiC, and others), which may require a high thermal/electrical conductivity chip interconnect for proper heat dissipation and an overall green, lead-free strategy.

The lead-free and high conductivity die attach system may enable a higher voltage and power supply in a dedicated system, which may enable device shrinking with less material for the same or even better electrical performance. Thereby, materials for both, front end and back end production may be saved.

In various embodiments, an interconnect is provided by a thin (e. g., tens to hundreds of nanometers to a few micrometers) plating of a chip carrier and/or the chip backside (its last layer) with Sn, Bi and/or Zn (more generally, metals with a low melting temperature, for example In 157° C., Sn 232° C., Bi 271° C., and/or Zn 419.5° C.) and metal particles (e. g., Ag and/or Cu) containing pastes that further include organic parts (resin, liquid/solvents, and/or others) forming a high conductivity intermetallic compound (IMC) contact by reaction of the metal particles included in the paste with the low temperature melting plating(s) of at least one of the bonding surfaces, e. g., with the chip and/or the chip carrier.

In various embodiments, a (lead free) highly conductive and reliable (due to a reduced stress transfer) chip attach interconnect system may be provided from a lead free die attach (DA) material and the related and fitting bonding surface(s), e. g., a solder layer on the chip and/or a further solder layer on the chip carrier.

A high thermal conductivity may be ensured by the highly filled paste or film that may be used for the die attach material, wherein “highly filled” means a high content of metal particles that include or consist of silver and/or copper. The high content of metal particles may be in a range from about 65 wt % to about 99 wt %.

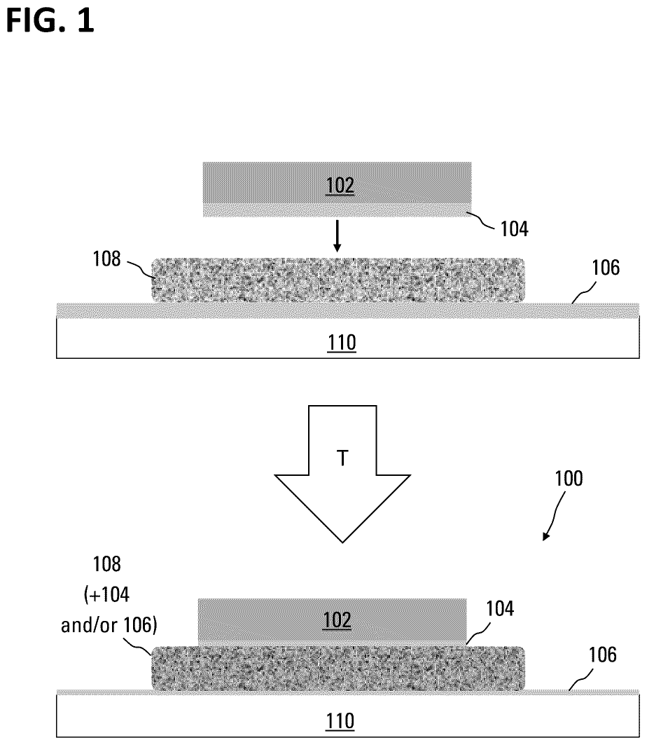

FIG. 1 illustrates a method of manufacturing a chip structure 100 in accordance with various embodiments, and shows a schematic cross-sectional view of the resulting chip structure 100 in accordance with various embodiments.

A chip 102 with a solder layer 104 may be provided.

The chip may be or include any kind of semiconductor chip with an integrated circuit. However, the high thermal and electrical conductivity that may be obtained in the chip structure 100 to be formed may be particularly beneficial for power chips, for example power chips including wide band-gap semiconductors (e. g., GaN, SiC, and others).

Furthermore, a chip carrier 110 with a further solder layer 106 may be provided. The chip carrier 110 may be or include any suitable type of chip carrier 110, for example a leadframe, e. g., a copper leadframe.

A chip attach layer 108 may be provided. The chip attach layer 108 may include a metal having a first melting point. The metal may for example be provided as metal particles included (e. g., dispersed) in the chip attach layer 108. The chip attach layer 108 may for example be provided as a (dispensable) paste or as a (solid but flexible) film. The metal may for example include or consist of silver and/or copper, for example essentially pure silver, pure copper, a mixture of silver and copper, and/or alloys of silver and/or copper. Besides the metal, the chip attach layer 108 may for example include organic parts like resin(s), solvent(s)/liquid(s) and/or additives like fluxes, surface reactive and activation substances.

At least one of the solder layer 104 and the further solder layer 106 may include or consist of a solder material having a second melting point lower than the first melting point. The solder material having the second melting point may for example be or include a metal having a low melting point, like for example indium (In), tin (Sn), bismuth (Bi), and/or zinc (Zn), a mixture or alloys thereof. Exemplary alloys are Sn₅Sb and SnAg.

As indicated in FIG. 1, the chip 102 may be arranged on the chip carrier 110 with the solder layer 104 and the further solder layer 106 facing each other.

The chip attach layer 108 may be arranged between the chip 102 and the chip carrier 110. Even though FIG. 1 shows the chip attach layer 108 as being arranged on the chip carrier 110, the chip attach layer 108 may generally be arranged on the chip 102 instead, or on both, the chip 102 and the chip carrier 110.

In various embodiments, an intermetallic phase between the solder material having the second melting temperature (which may originate either from the solder layer 104 on the chip 102 and/or from the further solder layer 106 on the chip carrier 110) and the metal of the chip attach layer 108 may be formed by melting the solder material having the second melting point.

In other words, by heating the solder layer 104 and/or the further solder layer 106 and the chip attach layer 108 (typically, the whole arrangement is heated as a unit in an oven) to or above the second melting point, the solder layer 104 and/or the further solder layer 106 (at least one of which includes or consists of the solder material having the second melting point) is melted.

The molten solder material may react with the (unmolten) metal of the chip attach layer 108 to form an intermetallic compound IMC, also referred to as an intermetallic phase.

The solder material may diffuse into the chip attach layer 108 to react with the metal in the chip attach layer 108. Depending on whether only one or both of the solder layer 104 and the further solder layer 106 include the solder material having the second melting point, the solder material may diffuse into the chip attach layer 108 from either the chip side, or the chip carrier side, or from both sides.

In various embodiments, the term “solder layer” and “further solder layer”, respectively, may refer to the suitability of the solder layer 104 and of the further solder layer 106 for forming a solder connection, e. g. of having something soldered thereto.

At least one of the solder layer 104 and the further solder layer 106 (optionally both) may include the solder material having the second melting point and thus be configured to contribute a reaction partner for forming the intermetallic compound when heated to or above the second temperature.

The solder layer 104 and the further solder layer 106 may in various embodiments both include the solder material having the second melting point. The solder layer 104 and the further solder layer 106 may include or consist of the same solder material (thus, the second melting point of both may be the same), or the solder material included in or forming the solder layer 104 may differ from the solder material included in or forming the further solder layer 106 (thus, the second melting point of the (solder material of the) solder layer 104 may differ from the second melting point of the (solder material of the) further solder layer 106.

In various embodiments, more than one solder material (i. e., with possibly different melting points) may be included in the solder layer 104, and/or more than one solder material may be included in the further solder layer 106.

Depending on specifics of the solder layer 104, the further solder layer 106, and the chip attach layer 108, an origin of the solder material in the solder layer 104 and/or the further solder layer 106 may be determined from a gradient of the solder material over the chip attach layer 108, remnants of the solder material in the solder layer 104 and/or the further solder layer 106, a porosity of the chip attach layer 108 (e. g., of the intermetallic compound), and/or other diagnostics.

The intermetallic compound may in various embodiments form a porous structure. The porous structure may alleviate stress on the chip 102 and thereby increase a reliability of the chip structure 100.

In various embodiments, a fine porous structure extending through the whole chip attach layer 108 may be obtained if the solder material containing layer of the solder layer 104 and the further solder layer 106 is formed with a suitable thickness.

“Suitable thickness” in accordance with various embodiments may mean that the layer is thick enough to provide a sufficient amount of solder material for reacting with the metal of the chip attach layer 108 all the way (or, if the solder material is provided from the chip side and from the chip carrier side, at least half way) through the chip attach layer 108, but on the other hand thin enough to avoid that an excessive among of solder material reacts too fast with the metal of the chip attach layer 108, thereby possibly forming a barrier with the intermetallic compound that may hinder further diffusion through the chip attach layer 108.

In various embodiments, a suitable thickness may for example be in the range from about 500 nm to about 5 μm, for example between about 1 μm and 3 μm.

In various embodiments, nickel may be avoided in the solder material containing layer of the solder layer 104 and the further solder layer 106. In particular in the case of the chip carrier 110, which may include or consist of copper, the copper may react with potential excessive solder material (e. g., to form CuSn in case of Sn as the solder material) and thereby possibly help avoiding a too fast formation of the intermetallic compound IMC. Such a reaction could possibly be inhibited by a nickel layer that may prevent the (excessive) solder material from reacting with a material (e. g., copper) of the chip carrier 110.

In various embodiments, the temperature for melting the solder material may be selected in accordance with the solder material(s) present in the solder layer 104 and/or the further solder layer 106.

For example, the solder material may be heated to or above 157° C. in case of indium, to or above 232° C. in case of tin, to or above 271° C. in case of bismuth, and/or to or above 419.5° C. in case of zinc. All of these temperatures may be lower than the melting temperature of the metal in the chip attach layer 108.

In a case of a chip attach layer 108 having a maximum curing temperature, the solder material may be selected accordingly. In various embodiments, the temperature for melting the solder material may for example be kept at or below 270° C.

A typical temperature for forming the intermetallic compound may for example be around 250° C., for example for the solder material including or consisting of tin, e. g. Sn₅Sb or SnAg.

In the following, some results of exemplary embodiments are shown.

The following material/structural combinations were realized:

| | Further | Further | Solder | Solder | |
|---|---|---|---|---|---|
| | solder layer | solder layer | layer | layer | |
| Chip attach | (chip carrier) | (chip carrier) | (chip) | (chip) | Group |
| material | Sn | NiSn | Sn | NiSn | # |
| sinter paste with | | X | X | | 1 |
| high amount of | | | | | |
| Ag particles | | | | | |
| sinter paste with | | X | | X | 2 |
| high amount of | | | | | |
| Ag particles | | | | | |
| sinter paste with | X | | X | | 3 |
| high amount of | | | | | |
| Ag particles | | | | | |
| sinter paste with | X | | | X | 4 |
| high amount of | | | | | |
| Ag particles | | | | | |
| adhesive with | X | | X | | 5 |
| high amount of | | | | | |
| Ag particles | | | | | |
| adhesive with | X | | | X | 6 |
| high amount of | | | | | |
| Ag particles | | | | | |
| adhesive with | | X | X | | 7 |
| high amount of | | | | | |
| Ag particles | | | | | |
| adhesive with | | X | | X | 8 |
| high amount of | | | | | |
| Ag particles | | | | | |

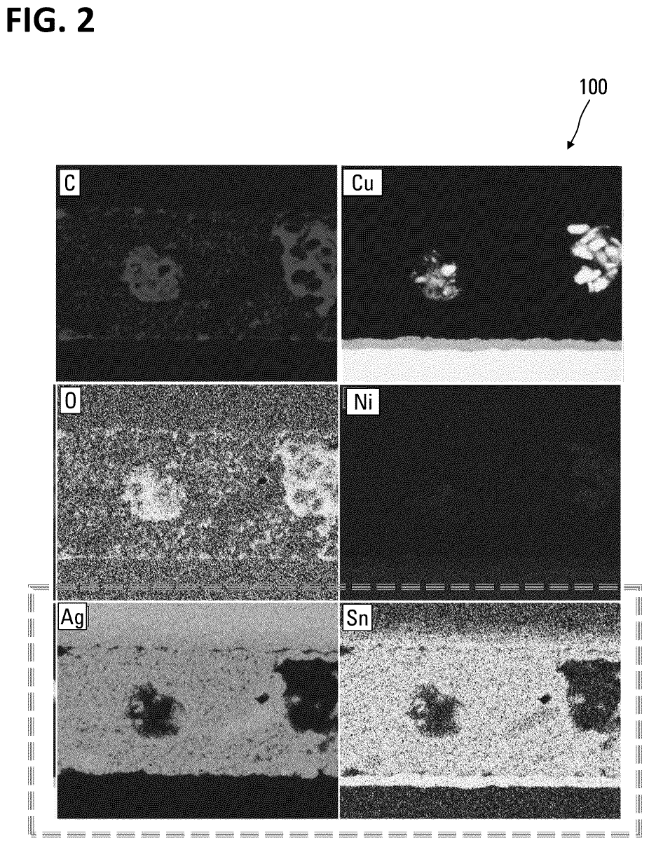

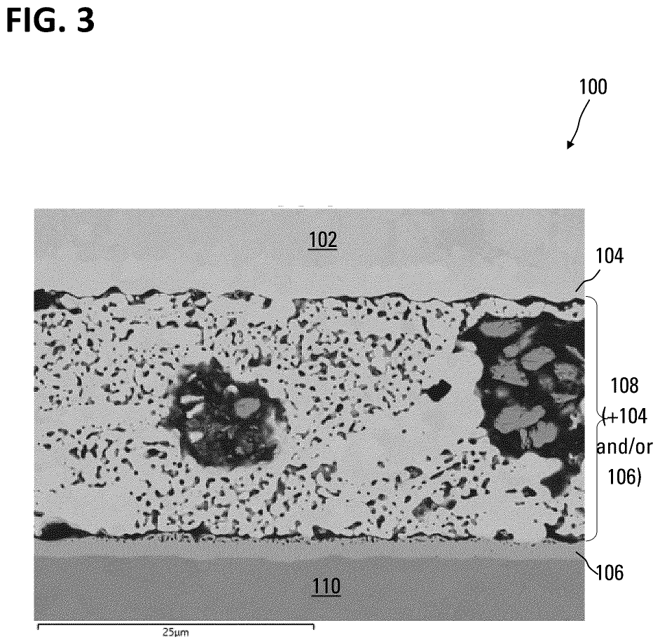

FIG. 2 shows distributions of six different elements (C, Cu, O, Ni, Ag, Sn) over the cross-section of a chip structure 100 in accordance with various embodiments obtained via scanning electron microscopy, and FIG. 3 shows an electron microscopy image of the cross-section of the chip structure 100 of FIG. 2. To avoid crowding, identification of the elements of the chip structure 100 was omitted in FIG. 2. FIG. 3 or FIG. 1 may be used for reference.

The results of FIGS. 2 and 3 are for Group #3, which means that a sinter paste that contains a large amount of silver particles, was used as in the chip attach layer 108, and nickel layers were arranged on the chip 102 as the solder layer 104 and on the chip carrier 110 as the further solder layer 106, respectively.

In FIG. 2, the bottom two distributions highlighted by the box indicate silver (Ag) and tin (Sn), respectively, which form the intermetallic phase.

As can be seen there, and also in FIG. 3, a very fine and homogeneous distribution of Sn from the bonding surfaces (the solder layer 104 and the further solder layer 106) into the chip attach layer 108 is obtained. Fine pores (shown in black) are distributed throughout the chip attach layer 108.

Region containing carbon (C) and/or oxygen (O) may indicate locations where organic portions of the chip attach material (e. g., the paste or film) remain. These regions may show an inhomogeneous distribution with the intermetallic phase.

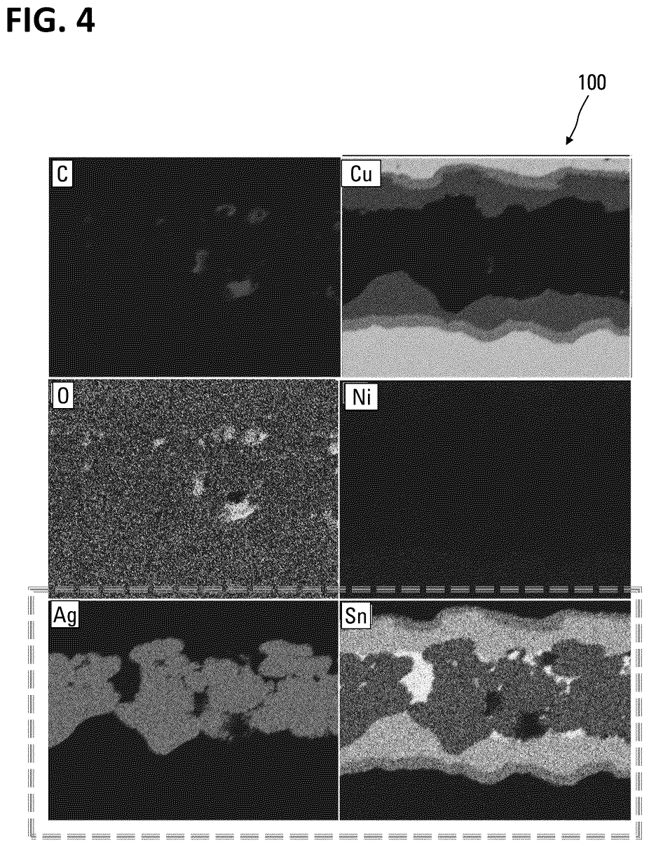

FIG. 4 shows distributions of six different elements over the cross-section of a further embodiment of a chip structure 100 obtained via scanning electron microscopy;

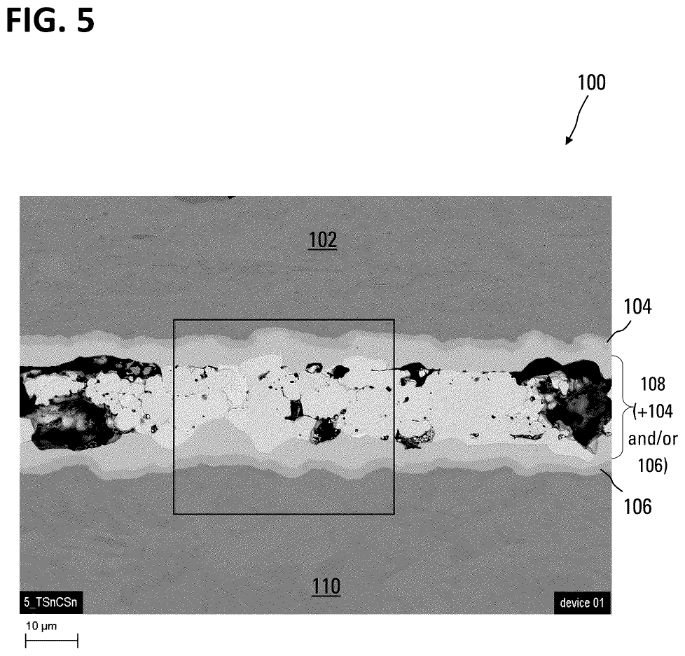

FIG. 5 shows an electron microscopy image of the cross-section of the chip structure 100 of FIG. 4 in an area that extends beyond the portion shown in FIG. 4. To avoid crowding, identification of the elements of the chip structure 100 was omitted in FIG. 4. FIG. 5 or FIG. 1 may be used for reference.

FIGS. 4 and 5 show results for Group 5. In other words, both, the solder layer 104 and the further solder layer 106 include tin, but no nickel. As can be seen in FIGS. 4 (the region highlighted by the box) and FIG. 5, a very fine and homogeneous distribution of the tin in the chip attach layer 108 is obtained.

Since the depot of Sn that is provided in the relatively thin solder layer 104 and further solder layer 106 (each with a thickness of between about 1 μm and 3 μm) for interdiffusion into the Ag particles of the chip attach layer 108 and forming of Ag rich AgₓSn_{y} phases is quite limited, a fast interdiffusion of Sn into the metal layer below or vice versa may occur.

The Ag-Sn-system may have a tin-rich eutectic (96.2 at % Sn, melting temperature 221° C.). Similar to the case of Cu-Sn, intermetallic phases may be encountered on a tin-poor side. A eutectic phase (e-phase) with the stoichiometry Ag₃Sn may show, just like for the Cu₃Sn phase, a narrow region of homogeneity of the Hume-Rothery-type. A non-eutectic phase (z-phase), a ternary Ag-Cu-Sn-system, may be stable over a broader range of concentrations. Its extent on the side facing the tin may strongly depend on temperature. Both phases may melt peritectically at temperatures of 480° C. or 724° C., respectively.

In both, the Cu-Sn-system, and in the Ag-Sn-System, the Ag is not soluble in Sn, but the other way around, up to 11.5 at % of tin may be dissolved in solid silver.

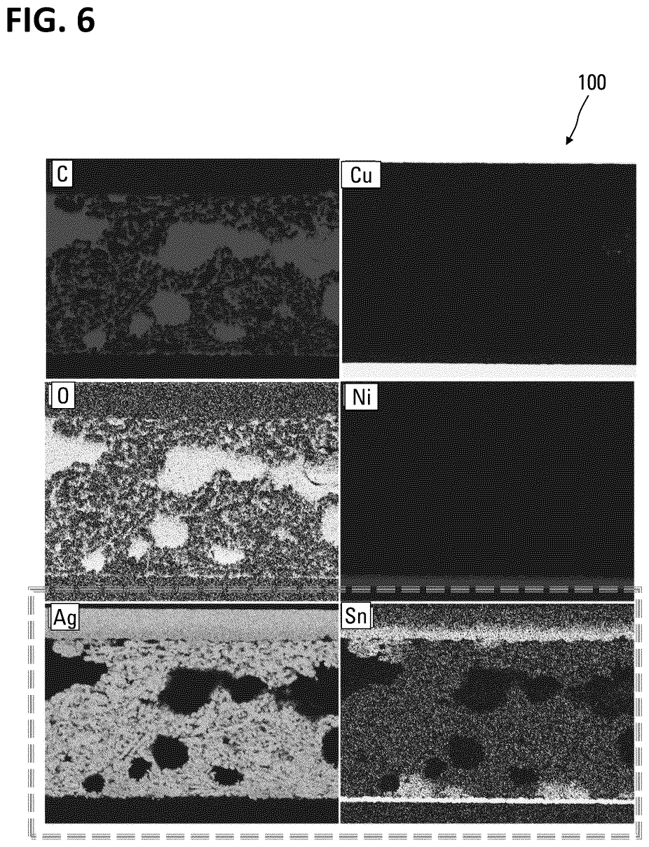

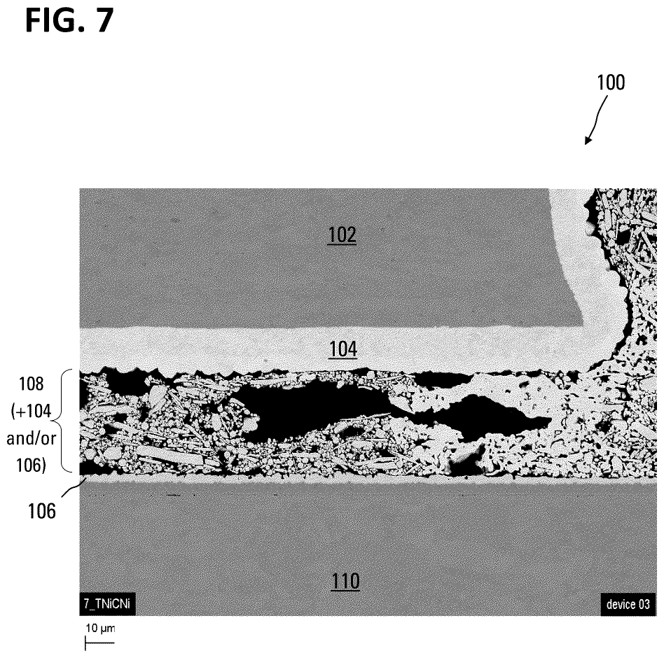

FIG. 6 shows distributions of six different elements over the cross-section of a yet further embodiment of a chip structure 100 obtained via scanning electron microscopy, and FIG. 7 shows an electron microscopy image of a cross-section of a chip structure of the same group, but a different specimen. To avoid crowding, identification of the elements of the chip structure 100 was omitted in FIG. 6. FIG. 7 or FIG. 1 may be used for reference.

The results of FIGS. 6 and 7 are for Group #7. In Group #7, the solder layer 104 includes tin without nickel, but the further solder layer 106 includes tin and nickel.

As can be seen in FIGS. 6 (bottom right panel), the distribution of tin in the chip attach layer 108 is less homogeneous than for the above described Groups 3 and 5. Nevertheless, an intermetallic phase is obtained at least partially throughout the chip attach layer 108, thereby improving a reliability of the chip structure 100 over prior art.

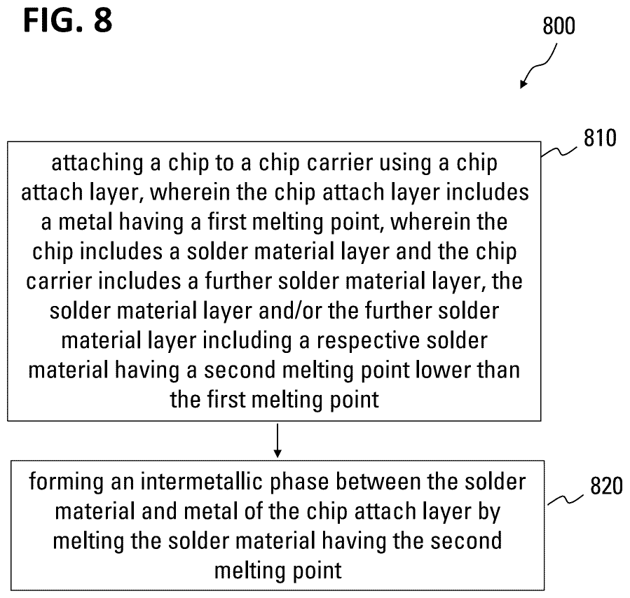

FIG. 8 shows a flow diagram of a method of manufacturing a chip structure (e. g., the chip structure 100 described above) in accordance with various embodiments.

The method includes attaching a chip to a chip carrier using a chip attach layer, wherein the chip attach layer includes a metal having a first melting point, wherein the chip includes a solder layer and the chip carrier includes a further solder layer, the solder layer and/or the further solder layer including a respective solder material having a second melting point lower than the first melting point (810), and forming an intermetallic phase between the solder material and metal of the chip attach layer by melting the solder material having the second melting point. (820)

Various examples will be illustrated in the following:

Example 1 is a method of manufacturing a chip structure. The method includes attaching a chip to a chip carrier using a chip attach layer, wherein the chip attach layer includes a metal having a first melting point, wherein the chip includes a solder layer and the chip carrier includes a further solder layer, the solder layer and/or the further solder layer including a respective solder material having a second melting point lower than the first melting point, and forming an intermetallic phase between the solder material and metal of the chip attach layer by melting the solder material having the second melting point.

In Example 2, the subject-matter of Example 1 may optionally include that the solder layer and/or the further solder layer is/are free of nickel.

In Example 3, the subject-matter of Example 1 or 2 may optionally include that the solder material includes or consists of tin.

In Example 4, the subject-matter of any of Examples 1 to 3 may optionally include that the solder material includes or consists of indium.

In Example 5, the subject-matter of any of Examples 1 to 4 may optionally further include forming an alloy between the metal of the chip attach layer and a further metal of the chip and/or between the metal of the chip attach layer and a further metal of the carrier.

In Example 6, the subject-matter of any of Examples 1 to 5 may optionally include that the melting includes heating the solder layer to a temperature in a range from 150° C. to 300° C.

In Example 7, the subject-matter of any of Examples 1 to 6 may optionally include that the melting includes heating the solder layer to a temperature in a range from 232° C. to 270° C.

In Example 8, the subject-matter of any of Examples 1 to 7 may optionally include that a thickness of the solder layer of the chip and/or a thickness of the further solder layer of the carrier is smaller than 5 μm.

In Example 9, the subject-matter of any of Examples 1 to 8 may optionally include that the chip attach layer is configured as a paste or as a film.

In Example 10, the subject-matter of any of Examples 1 to 9 may optionally include that, after forming the intermetallic phase, the chip attach layer includes a porous structure.

In Example 11, the subject-matter of any of Examples 1 to 10 may optionally include that the intermetallic phase has a porous structure.

In Example 12, the subject-matter of Example 10 or 11 may optionally include that pores of the porous structure have sizes in a range from about 20 nm to about 100 nm.

In Example 13, the subject-matter of any of Examples 1 to 12 may optionally include that the chip attach layer includes an organic adhesive.

In Example 14, the subject-matter of any of Examples 1 to 13 may optionally include that, after forming the intermetallic phase, the porous structure and the organic adhesive form an inhomogeneous distribution.

In Example 15, the subject-matter of any of Examples 1 to 14 may optionally include that the chip attach layer forms a form-fitting connection with the chip and the chip carrier, respectively.

In Example 16, the subject-matter of any of Examples 1 to 15 may optionally include that the solder material and further solder material are the same.

In Example 17, the subject-matter of any of Examples 1 to 15 may optionally include that the solder material and further solder material are different.

Example 18 is a chip structure. The chip structure may include a chip with a solder layer, a chip carrier with a further solder layer, and a chip attach layer attaching the chip to the chip carrier, wherein the chip attach layer includes an intermetallic phase formed between a solder material originating in the solder layer and metal of the chip attach layer and/or between a solder material originating in the further solder layer and metal of the chip attach layer by melting the solder material that has a lower melting point than the metal of the chip attach layer.

In Example 19, the subject-matter of Example 18 may optionally include that the solder layer and/or the further solder layer is/are free of nickel.

In Example 20, the subject-matter of Example 18 or 19 may optionally include that the solder material includes or consists of tin.

In Example 21, the subject-matter of any of Examples 18 to 20 may optionally include that the solder material includes or consists of indium.

In Example 22, the subject-matter of any of Examples 18 to 21 may optionally include that the chip attach layer further includes an alloy between the metal of the chip attach layer and a further metal of the chip and/or between the metal of the chip attach layer and a further metal of the carrier.

In Example 23, the subject-matter of any of Examples 18 to 22 may optionally include that the melting includes heating the solder layer to a temperature in a range from 150° C. to 300° C.

In Example 24, the subject-matter of any of Examples 18 to 23 may optionally include that the melting includes heating the solder layer to a temperature in a range from 232° C. to 270 C.

In Example 25, the subject-matter of any of Examples 18 to 24 may optionally include that a thickness of the solder layer of the chip and/or a thickness of the further solder layer of the carrier is smaller than 5 μm.

In Example 26, the subject-matter of any of Examples 18 to 25 may optionally include that a thickness of the solder layer of the chip and/or a thickness of the further solder layer of the carrier is smaller than 5 μm.

In Example 27, the subject-matter of any of Examples 18 to 26 may optionally include that, after forming the intermetallic phase, the chip attach layer includes a porous structure.

In Example 28, the subject-matter of any of Examples 18 to 27 may optionally include that the intermetallic phase has a porous structure.

In Example 29, the subject-matter of any of Examples 18 to 28 may optionally include that the chip attach layer includes an organic adhesive.

In Example 30, the subject-matter of any of Examples 18 to 29 may optionally include that, after forming the intermetallic phase, the porous structure and the organic adhesive form an inhomogeneous distribution.

In Example 31, the subject-matter of any of Examples 18 to 30 may optionally include that the solder material and further solder material are the same

In Example 32, the subject-matter of any of Examples 18 to 31 may optionally include that the solder material and further solder material are different

In Example 33, the subject-matter of any of Examples 18 to 30 may optionally include that the chip is a power chip.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of manufacturing a chip structure, the method comprising:
attaching a chip to a chip carrier using a chip attach layer, wherein the chip attach layer comprises a metal having a first melting point, wherein the chip comprises a solder layer and the chip carrier comprises a further solder layer, the solder layer and/or the further solder layer comprising a respective solder material having a second melting point lower than the first melting point; and
forming an intermetallic phase between the solder material and metal of the chip attach layer by melting the solder material having the second melting point.

2. The method of claim 1,
wherein the solder layer and/or the further solder layer is/are free of nickel.

3. The method of claim 1,
wherein the solder material comprises tin.

4. The method of claim 1,
wherein the solder material comprises indium.

5. The method of claim 1,
further comprising:
forming an alloy between the metal of the chip attach layer and a further metal of the chip and/or between the metal of the chip attach layer and a further metal of the carrier.

6. The method of claim 1,
wherein the melting comprises heating the solder layer to a temperature in a range from 150° C. to 300° C.

7. The method of claim 1,
wherein the melting comprises heating the solder layer to a temperature in a range from 232° C. to below 270° C.

8. The method of claim 1,
wherein a thickness of the solder layer of the chip and/or a thickness of the further solder layer of the carrier is smaller than 5 μm.

9. The method of claim 1,
wherein, after forming the intermetallic phase, the chip attach layer comprises a porous structure.

10. The method of claim 1,
wherein the chip attach layer comprises an organic adhesive.

11. A chip structure, comprising:
a chip with a solder layer;
a chip carrier with a further solder layer; and
a chip attach layer attaching the chip to the chip carrier;
wherein the chip attach layer comprises an intermetallic phase formed between a solder material originating in the solder layer and metal of the chip attach layer and/or between a solder material originating in the further solder layer and metal of the chip attach layer by melting the solder material that has a lower melting point than the metal of the chip attach layer.

12. The chip structure of claim 11,
wherein the solder layer and/or the further solder layer is/are free of nickel.

13. The chip structure of claim 11,
wherein the solder material comprises or consists of tin.

14. The chip structure of claim 11,
wherein the solder material comprises or consists of indium.

15. The chip structure of claim 11,
wherein the chip attach layer further comprises an alloy between the metal of the chip attach layer and a further metal of the chip and/or between the metal of the chip attach layer and a further metal of the carrier.

16. The chip structure of claim 11,
wherein a thickness of the solder layer of the chip and/or a thickness of the further solder layer of the carrier is smaller than 5 μm.

17. The chip structure of claim 11,
wherein a thickness of the solder layer of the chip and/or a thickness of the further solder layer of the carrier is smaller than 5 μm.

18. The chip structure of claim 11,
wherein the chip attach layer comprises an organic adhesive.

19. The chip structure of claim 11,
wherein, after forming the intermetallic phase, the porous structure and the organic adhesive form an inhomogeneous distribution.

20. The chip structure of claim 11,
wherein the solder material and further solder material are the same.
